(19) United States
(12) Patent Application Publication
(10) Pub. No.: US 2004/0001601 A1
(43) Pub. Date: Jan. 1, 2004

(54) Electronic apparatus for adjusting brightness and flashing of lights in response to audio signals

(76) Inventor: Chao-Lang Wang, Taipei (TW)

Correspondence Address: BACON & THOMAS, PLLC, 625 SLATERS LANE, FOURTH FLOOR, ALEXANDRIA, VA, 22314

(21) Appl. No.: 10/180,346

(22) Filed: Jun. 27, 2002

(51) Int. Cl. H03G 3/00; H04B 1/00

(52) U.S. Cl. 381/124; 381/61

(57) ABSTRACT

The invention is to provide an electronic apparatus for adjusting brightness and flashing of lights in response to audio signals, which comprises at least one set of frequency-divider crossover network or protection circuit being in series or parallel for receiving output audio signals from a sound source and converting the audio signals having different frequencies or a full-frequency range into different current signals which are in turn outputted to at least one coupled source unit of light and drive the source unit of light to automatically adjust brightness and flashing of light in response to frequency of the audio signals.

### FIELD OF THE INVENTION

The present invention relates to adjustment of brightness and flashing of lights and more particularly to an improved electronic apparatus for adjusting brightness and flashing of lights (e.g., Christmas lights, stage lights for concert, ballroom lights, or the like) in response to audio signals.

### BACKGROUND OF THE INVENTION

Recently, electronics technology and material science have known a rapid and spectacular development. As an end, more inexpensive electronic products are available to consumers as the development of novel electronic components and more advanced manufacturing processes. Further, both features and quality of the electronic products are significantly improved. Furthermore, the rapid advances in semiconductor technology revolutionized electronics. In replacing their conventional electronic devices (e.g., vacuum-type counterparts), semiconductor-based electronic products brought smaller size (i.e., slim) for tailoring the needs of markets and consumers. Moreover, such electronic products are very convenient and thus are widely used among consumers. In nowadays many high quality while low price electronic products (e.g., Walkmans, bedside stereo, etc.) have become affordable among generally all consumers. However, a number of drawbacks are experienced by such consumer-oriented electronic products (e.g., general audio-video (AV) devices and multimedia devices). In detail, electronic equipment for controlling sound effect of the electronic product is still equipped with conventional speakers for outputting sound despite of a development of slimness and miniature thereof. As such, a reduction of sizes of the electronic products is still limited. Undesirably, improvements in both quality and volume of the speaker are still very limited due to design bottleneck.

The present inventor had invented a novel speaker for eliminating many drawbacks occurred to construction and manufacturing of conventional speakers. Such novel speaker had been filed concurrently both in Taiwan (i.e., one with application No. 89,117,124) and U.S. (i.e., one with Ser. No. 09/692,440) respectively. It is best illustrated in FIG. 1. As shown, a speaker 30 comprises a frame 31, a diaghragm 32 covered on an outer periphery of the frame 31, a resonant chamber 33 enclosed by the frame 31 and the diaghragm 32, a coil 34 wound around a middle part, and a magnetic element 35 in the middle part. In operation, a magnetic flux in the middle part change due to an excitation of the coil 34 may cause a high frequency attraction-and-repulsion effect in the magnetic element 35. As a result, the diaghragm 32 is vibrated and thus outputs a sound. Such construction can not only save space occupied by seat, core, and permanent magnet of a conventional speaker but also significantly reduce a thickness, an assembly and manufacturing cost of the speaker, and greatly increase a woofer quality and power thereof.

The present inventor thus desires to apply the above patent application to conventional lights (e.g., Christmas lights, stage lights for concert, ballroom lights, or the like) for increasing a sound and lighting effect since it can greatly reduce a size of the speaker and its cost. However, a typical Christmas light is electrically connected to a dedicate control circuit so that an embedded program of the control circuit may be enabled to automatically adjust brightness and flashing of the lights. Likewise, either stage light for concert or ballroom light is electrically connected to a dedicate control circuit so that either an embedded program of the control circuit may be enabled to automatically adjust or a disc jockey may manually adjust brightness and flashing of the lights. But a drawback is found. That is, an automatic adjustment of brightness and flashing of the electronic apparatus is infeasible since the control circuit does not has the capability of adjusting itself immediately for cooperating with a combination of the light and accompanying live music. As an end, a sound and lighting effect of live concert is compromised since the electronic apparatus does not function in harmony with the playing music and rhythm.

Thus, it is desirable to provide a novel electronic apparatus for adjusting brightness and flashing of lights in response to audio signals in order to overcome the above drawbacks of the prior art.

### SUMMARY OF THE INVENTION

The invention relates to an electronic apparatus for adjusting brightness and flashing of lights in response to audio signals. The electronic apparatus comprises at least one set of frequency-divider crossover network or protection circuit being in series or parallel for receiving output audio signals from a sound source. Further, various matching electronic devices (e.g., resistors, inductors, and capacitors) mounted on the frequency-divider crossover network or the protection circuit may be utilized to convert the audio signals having different frequencies or a full-frequency range into different current signals which are in turn outputted to at least one coupled source unit of light.

A primary object of the present invention is to utilize the frequency-divider crossover network to output the audio signals having different frequencies to each source unit of light so that the source unit of light is capable of automatically adjusting brightness and flashing of the lights in response to frequency of the audio signals.

Another object of the present invention is to utilize the protection circuit to output the audio signals having a full-frequency range to each source unit of light so that the source unit of light is capable of automatically adjusting brightness and flashing of the lights in response to frequency of the audio signals.

Still another object of the present invention is to provide a speaker in series with or parallel to each source unit of light. When the frequency-divider crossover network or the protection circuit is enabled to output the audio signals having different frequencies or a full-frequency range to each source unit of light, each source unit of light and the speaker are capable of automatically adjusting brightness and flashing of the lights and generating rhythm in response to frequency value of the audio signals. As an end, a sound and lighting effect is obtained.

The above and other objects, features and advantages of the present invention will become apparent from the following detailed description taken with the accompanying drawings.

### BRIEF DESCRIPTION OF THE DRAWINGS

FIG. 1 is a cross-sectional view of a speaker according to U.S. patent application Ser. No. 09/692,440;

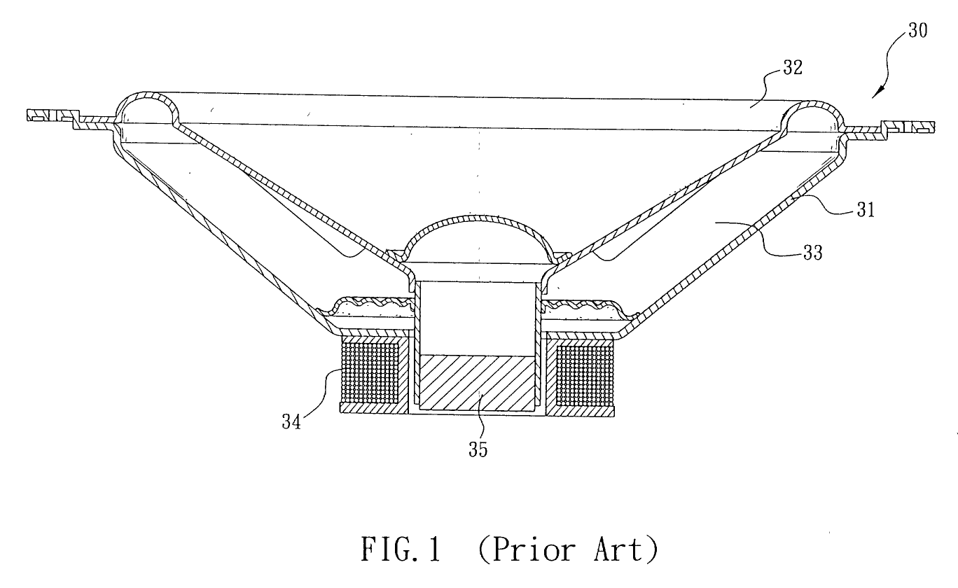

FIG. 2 is a schematic circuit diagram of a frequency-divider crossover network according to the invention;

FIG. 3 is a schematic circuit diagram of a preferred embodiment according to the invention;

FIG. 4 is a schematic circuit diagram of another preferred embodiment according to the invention;

FIG. 5 is a perspective view of a first configuration of the preferred embodiment according to the invention;

FIG. 6 is a perspective view of a second configuration of the preferred embodiment according to the invention; and

FIG. 7 is a perspective view of a third configuration of the preferred embodiment according to the invention.

### DETAILED DESCRIPTION OF THE PREFERRED EMBODIMENTS

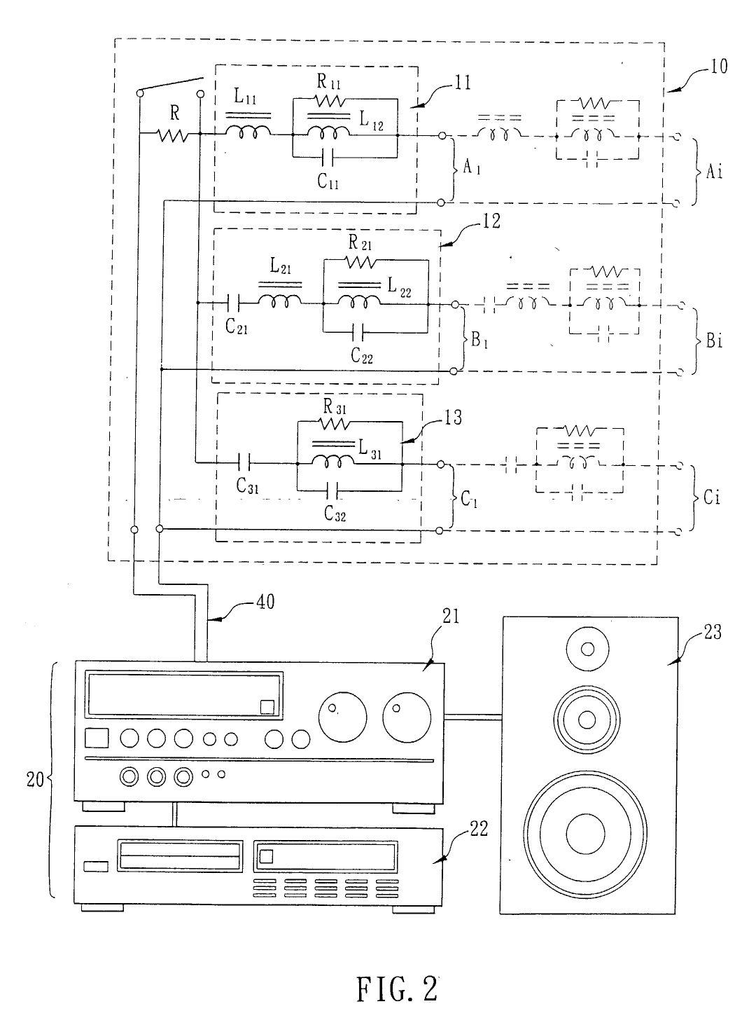

Referring to FIG. 2, there is shown an electronic apparatus for adjusting brightness and flashing of lights in response to audio signals in accordance with the invention. The electronic apparatus comprises a frequency-divider crossover network 10 having a plurality of frequency-divider crossover circuits (three frequency-divider crossover circuits 11, 12, and 13 are shown). The number of frequency-divider crossover circuits may be varied depending on applications or designs. Each of the frequency-divider crossover circuits 11, 12 and 13 can receive audio signals sent from a sound source 20. Further, various matching electronic devices (e.g., resistors R₁₁, R₂₁, . . . Rᵢⱼ, inductors L₁₁, L₂₁, . . . Lᵢⱼ, and capacitors C₁₁, C₂₁, . . . Cᵢⱼ) mounted on the frequency-divider crossover network 10 may be utilized to convert the audio signals having different frequencies or a full-frequency range into corresponding current signals. In the invention, the frequency-divider crossover circuits may be electrically connected in series or parallel depending on applications or designs. The sound source means any device capable of generating an audio signal. In the invention, it is implemented as a general AV and multimedia device 22 or a sound effect amplifier 21 (or speaker 23) connected to the AV and multimedia device 22 for outputting the audio signals generated to the frequency-divider crossover network 10 via output ports thereof. In the invention (see FIG. 2), the AV and multimedia device (e.g., CD player) 22 generates audio signals which are amplified by the sound effect amplifier 21. Next, the amplified audio signals are outputted to the frequency-divider crossover network 10 via a signal line 40. At the same time, the sound effect amplifier 21 outputs the audio signals to the speaker 23 coupled thereto. Moreover, the frequency-divider crossover circuits 11, 12 and 13 shown in FIG. 2 are simply a circuit pattern of a plurality of implementations of the invention. Note that the scope of the invention set forth in the claims is not limited by the described specific implementation. It is appreciated by those skilled in the art that the frequency-divider crossover network or frequency-divider crossover circuits may be replaced by other suitable devices or circuits for converting the audio signals sent from the sound source 20 into current signals without departing from the scope and spirit of the invention.

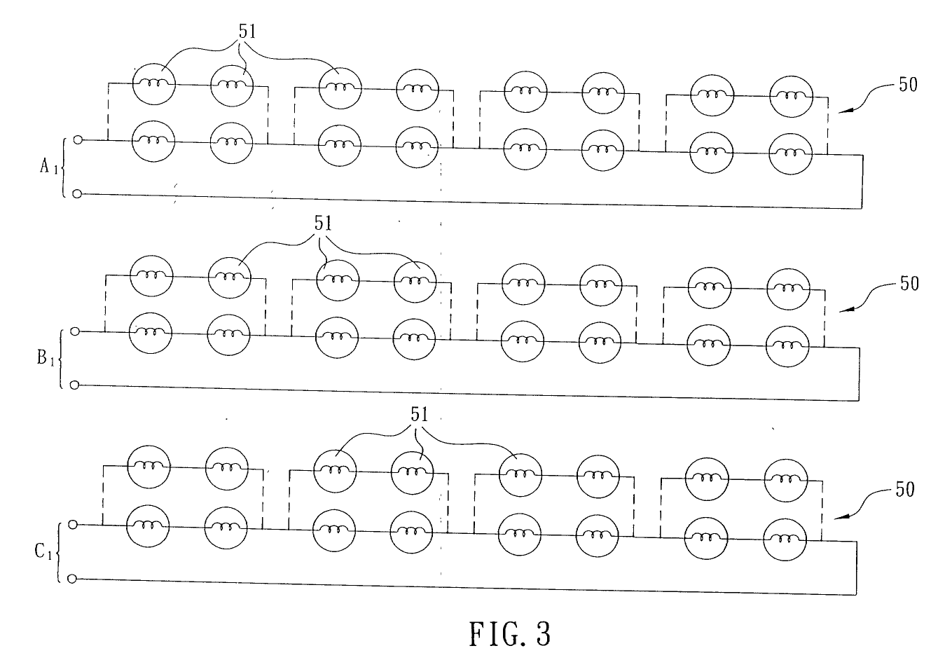

Referring to FIG. 3, there is shown a preferred embodiment of the invention. The electronic apparatus further comprises a plurality of light assemblies 50. Each light assembly 50 is electrically connected to output terminals A₁, B₁ and C₁ of the frequency-divider crossover circuits 11, 12 and 13 respectively, as shown in FIG. 2. Thus, the frequency-divider crossover circuit 11, 12 and 13 may be enabled to, within a predetermined range of frequency whether a full-frequency range or different frequencies, convert the received audio signals into corresponding current signals which are in turn outputted to each coupled light assembly 50 via the output terminals A₁, B₁ and C₁. As a result, each light assembly 50 is capable of automatically adjusting brightness and flashing of each light assembly 50 in response to frequency and strength of the current signals (i.e., volume of the audio signals or tone of rhythm). In the embodiment, each of the light assemblies 50 is either a source unit of light (e.g., lamp 51 or any other light-emitting element being enabled as current increase) or a plurality of source units of light 51 depending on applications or designs. Further, the light assemblies 50 may be connected in series or parallel.

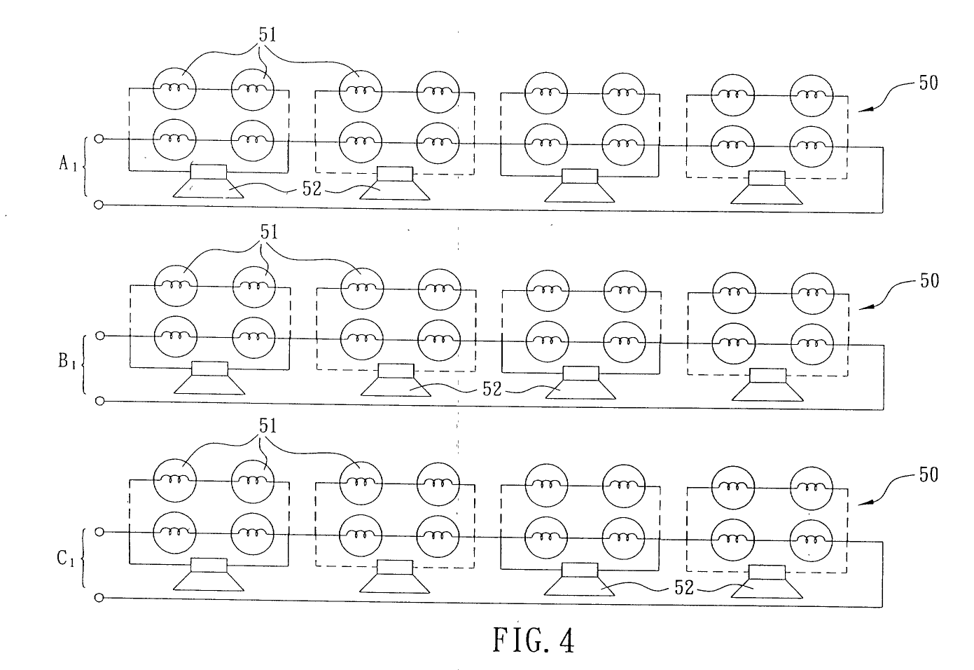

Referring to FIG. 4, there is shown another preferred embodiment according to the invention. In addition to the plurality of light assemblies 50, the invention further comprises a speaker 52 in series with or parallel to each light assembly 50. Thus, the frequency-divider crossover circuits 11, 12 and 13 may be enabled to, within a predetermined range of frequency whether a full-frequency range or different frequencies, convert the received audio signals into corresponding current signals which are in turn outputting to each coupled light assembly 50 via the output terminals A₁, B₁ and C₁ and, at the same time, driving the speakers 52. As a result, the source units of light 51 and the speakers 52 are capable of automatically adjusting brightness and flashing of the light and generating rhythm in response to frequency and strength of the current signals (i.e., volume of the audio signals or tone of rhythm) respectively. As an end, a sound and lighting effect is obtained.

In the invention, it is particularly noted that various matching electronic devices mounted on the frequency-divider crossover circuits 11, 12 and 13 are specifically designed with respect to an output bandwidth of the audio signal. Hence, it is possible of generating a required crossover frequency by adjusting characteristic values of the electronic devices. Also, the frequency-divider crossover circuits 11, 12 and 13 may be enabled to convert the audio signals within a predetermined range of frequency into required current signals. The current signals are in turn utilized to drive the source units of light 51 and the speakers 52 connected to the frequency-divider crossover circuits 11, 12 and 13 respectively. As such, the invention may design characteristic values and connections of the matching electronic devices on the frequency-divider crossover circuits 11, 12 and 13 for enabling the frequency-divider crossover circuits 11, 12 and 13 to generate current signals which are maintained within a safe load range of the source units of light 51 and the speakers 52. As a result, the bandwidth of the audio signal outputted from the sound source is prevented from exceeding an allowable value. Otherwise, excessive large current signals generated by the frequency-divider crossover circuits 11, 12 and 13 may damage the source units of light 51 and the speakers 52 since it has exceeded an allowable maximum load range of the source units of light and the speakers 52. Moreover, in the invention an over-current (or over-voltage) protection circuit is provided at a line interconnected each of the frequency-divider crossover circuits 11, 12 and 13 and each of the output terminals of the sound source for maintaining the current signals generated by the frequency-divider crossover circuits 11, 12 and 13 within the allowable maximum load range of the source units of light 51 and the speakers 52. In addition, the invention incorporates a plurality of protection circuits for replacing the frequency-divider crossover circuits 11, 12 and 13 for reducing a manufacturing cost. The protection circuits are enabled to convert audio signals sent from the sound source into current signals within the allowable maximum load range of the source units of light 51 and the speakers 52. Thus, it is appreciated by those skilled in the art that the protection circuit may be formed as either an integral part of the frequency-divider crossover network 10 or an independent circuit connected to the frequency-divider crossover network 10 without departing from the scope and spirit of the invention.

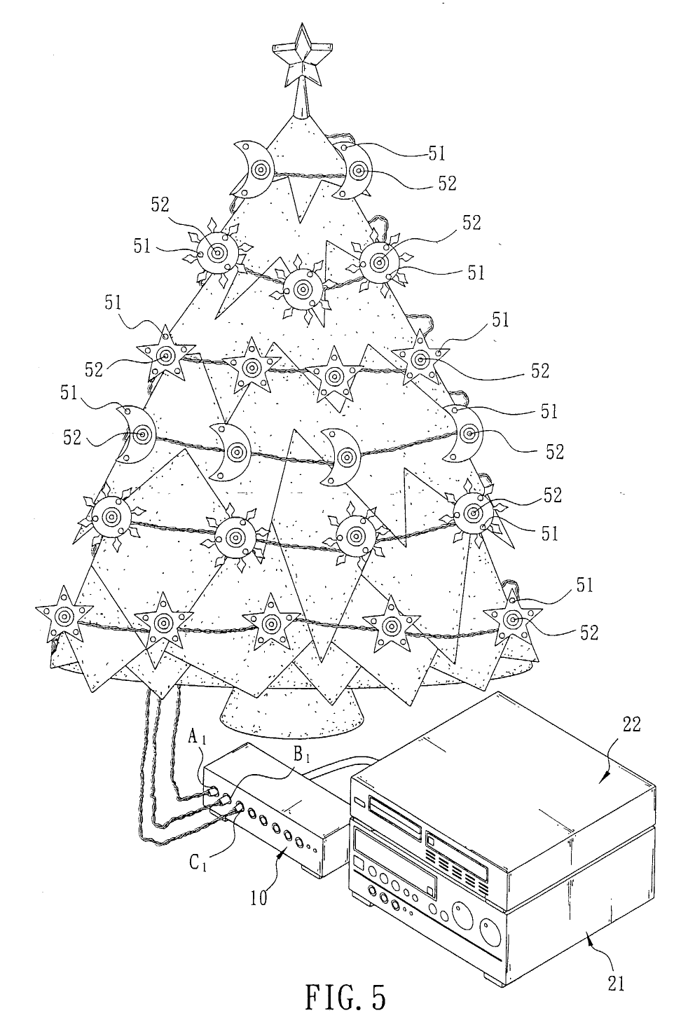

Referring to FIG. 5 in conjunction with FIG. 4, a first configuration of the preferred embodiment of the invention is illustrated. As shown, each light assembly 50 is designed to has a unique shape (e.g., star, crescent, or sun in FIG. 5) of a decoration. Further, the source units of light 51 and the speaker 52 are mounted on each light assembly 50 to form a plurality of independent lamp strings. Each source unit of light 50 is electrically connected to the output terminals A₁, B₁, and C₁. Thus, audio signals generated by the AV and multimedia device 22 may be directly (or indirectly via the sound effect amplifier 21 for amplification) outputted to the frequency-divider crossover network 10. And in turn, the audio signals are sent to the light assemblies 50 via the output terminals A₁, B₁, and C₁ of the frequency-divider crossover network 10 for driving the source units of light 51 and the speaker 52 simultaneously. As a result, the source units of light 51 and the speaker 52 are capable of automatically adjusting brightness and flashing of light and generating rhythm in response to volume of the audio signals or tone of rhythm. As an end, a sound and lighting effect is obtained.

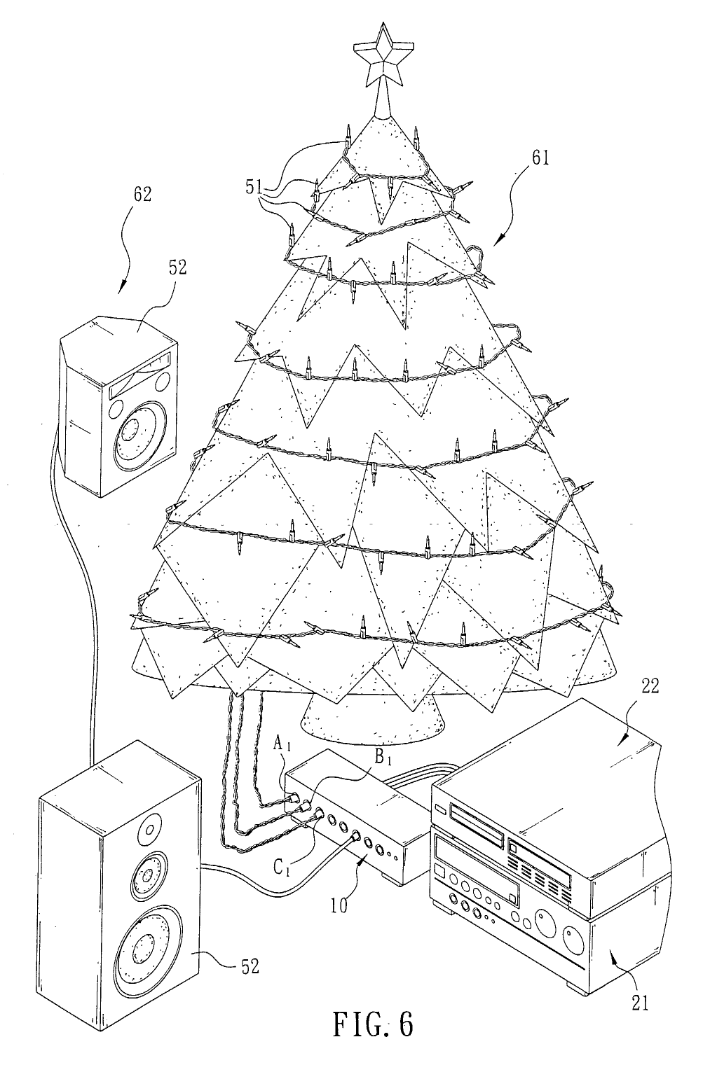

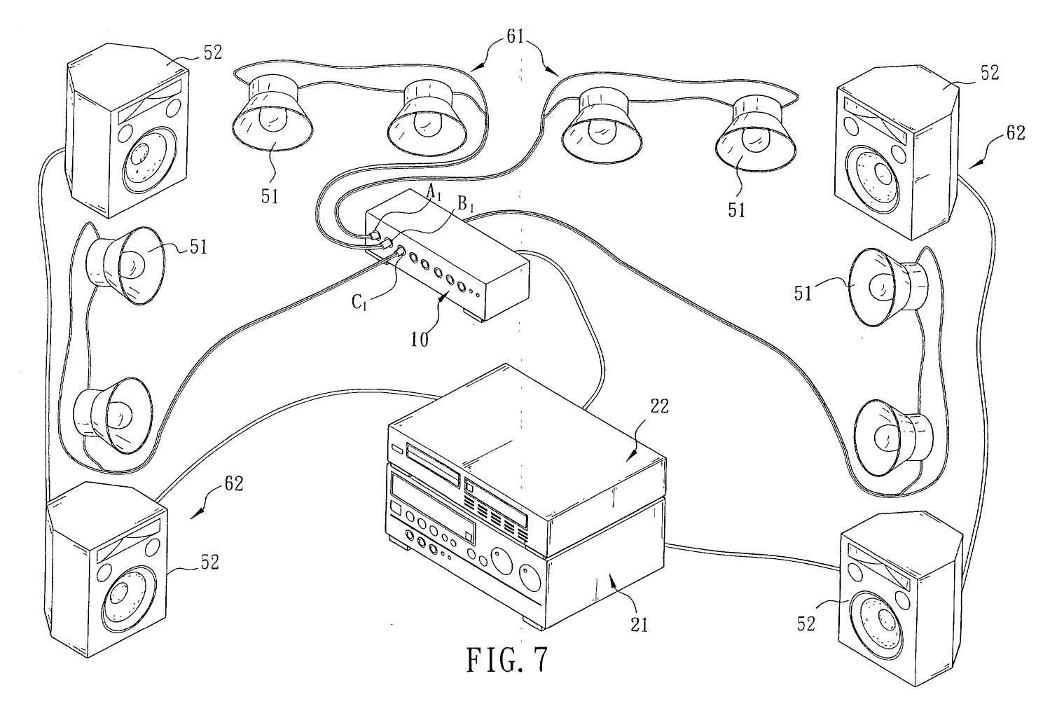

Referring to FIGS. 6 and 7 in conjunction with FIG. 4, second and third configurations of the preferred embodiment according to the invention are illustrated. The source units of light 51 and the speaker 52 form independent lamp strings 61 and speaker assembly 62 in series or parallel. The lamp strings 61 and the speaker assembly 62 are electrically connected to the output terminals A₁, B₁, and C₁ respectively. Thus, audio signals generated by the AV and multimedia device 22 may be directly (or indirectly via the sound effect amplifier 21 for amplification) converted into current signals by the frequency-divider crossover network 10. And in turn, the current signals are sent to the lamp strings 61 and the speaker assembly 62 respectively. As a result, the source units of light 51 of the lamp strings 61 are capable of automatically adjusting brightness and flashing of each source unit of light 51 of the lamp strings 61 and generating rhythm by driving the speakers of the speaker assembly 62 at the same time in response to volume of the audio signals or tone of rhythm. As an end, a sound and lighting effect is obtained.

While the invention has been described by means of specific embodiments, numerous modifications and variations could be made thereto by those skilled in the art without departing from the scope and spirit of the invention set forth in the claims.

What is claimed is:

1. An electronic apparatus for adjusting brightness and flashing of lights in response to audio signals comprising:
at least one conversion circuit each for receiving audio signals outputted from a sound source; and
at least one light assembly each electrically connected to a plurality of output terminals of the conversion circuit so that in response to a receiving of corresponding current signals sent from the conversion circuit, each light assembly is capable of adjusting brightness and flashing thereof in response to frequency and strength of the current signals.

2. The electronic apparatus of claim 1, wherein the conversion circuit is a frequency-divider crossover network for receiving the audio signals outputted from the sound source, the audio signals being converted into the corresponding current signal based on predetermined different crossover frequency ranges.

3. The electronic apparatus of claim 1, wherein the conversion circuit is a protection circuit for receiving the audio signals outputted from the sound source, the audio signals being converted into the corresponding current signal based on a predetermined safe load range.

4. The electronic apparatus of claim 1, wherein the light assembly comprises at least one interconnected source unit of light.

5. The electronic apparatus of claim 1, further comprising at least one speaker connected to each light assembly.

6. The electronic apparatus of claim 1, further comprising at least one speaker connected to the output terminals of the conversion circuit.

7. The electronic apparatus of claim 2, wherein the frequency-divider crossover network comprises at least one interconnected frequency-divider crossover circuit each for receiving the audio signals outputted from the sound source, so that characteristic values of various matching electronic devices mounted on each frequency-divider crossover circuit is capable of converting the audio signals having different frequencies into the corresponding current signals.

8. The electronic apparatus of claim 7, further comprising a protection circuit at a line interconnected each frequency-divider crossover circuit and the sound source for maintaining the current signals generated by each frequency-divider crossover circuit within the predetermined safe load range.

9. The electronic apparatus of claim 7, wherein the characteristic values of the matching electronic devices are designed to, within a formed crossover frequency of each frequency-divider crossover circuit, convert the audio signals having a specific frequency into the corresponding current signals within the predetermined safe load range.
